(19) United States
(12) Patent Application Publication
(10) Pub. No.: US 2018/0077803 A1
(43) Pub. Date: Mar. 15, 2018

(54) PASSIVES IN THIN FILM

(71) Applicant: QUALCOMM Incorporated, San Diego, CA (US)

(72) Inventors: Changhan Hobie YUN, San Diego, CA (US); David Francis BERDY, San Diego, CA (US); Chengjie ZUO, San Diego, CA (US); Jonghae KIM, San Diego, CA (US); Niranjan Sunil MUDAKATTE, San Diego, CA (US); Mario Francisco VELEZ, San Diego, CA (US); Shiqun GU, San Diego, CA (US)

(21) Appl. No.: 15/261,838

(22) Filed: Sep. 9, 2016

(51) Int. Cl. H05K 1/18; H05K 1/11; H05K 1/02; H05K 3/00; H05K 3/30; H05K 3/40

(52) U.S. Cl. CPC H05K 1/185; H05K 1/115; H05K 1/0298; H05K 2201/0317; H05K 3/30; H05K 3/4038; H05K 3/007

(57) ABSTRACT

Due to the presence of a glass substrate, it is difficult to fabricate thin conventional passive-on-glass (POG) devices. Also glass dicing has been a throughput bottleneck in fabricating the conventional POG device. To address such disadvantages, devices without the glass substrates are proposed. Support structures may be provided to provide mechanical support. The devices are significantly thinner and allow access to the passive components from both first and second surfaces, which are opposite and exposed surfaces. The proposed POM devices may also be incorporated in a package substrate.

### FIELD OF DISCLOSURE

The field of the disclosed subject matter passive devices and to methods of manufacturing the passive devices. In particular, the field of the disclosed subject matter relates to passive devices in thin film and to methods of manufacturing the passive devices in thin film.

### BACKGROUND

Passive devices (e.g., capacitors, inductors, etc.) may be manufactured on substrates such as glass. FIG. 1A illustrates a stage of fabricating a conventional passives-on-glass (POG) device. As seen, multiple POG devices are provided on one side of a glass substrate 110. The adjacent POG devices are separated by a dicing street 160. The glass substrate 110 is diced at the dicing street 160 to arrive at an individual POG device illustrated in FIG. 1B.

The conventional POG device in FIG. 1B includes the diced glass substrate 110 and first, second and third polymer layers 140, 130, 120 on the glass substrate 110. A passive element—e.g., a capacitor—is formed in the third polymer layer 120. The capacitor includes a dielectric 127 between two electrodes 125 and 129. Solder joints 150 above the first polymer layer 140 are coupled with the electrodes 125 and 129 through the first polymer layer connects 145 and through the second polymer layer connects 135. Due to the presence of the glass substrate 110, electrical coupling with external devices can only take place through the first polymer layer connects 145, i.e., through only one surface of the POG device.

In conventional passives-on-glass (POG) manufacturing processes, glass dicing (e.g., laser, saw) has been a throughput bottleneck, which in turn increases costs. Also, the width of the dicing street 160 must provide sufficient margin for the dicing process. As a result, dicing often leaves behind a deviation in the glass substrate 110. For example, as seen in FIG. 1B, the remaining glass substrate 110 is wider than the polymer layers 140, 130, 120.

Further, the glass substrate 110 significantly increases the thickness of the POG device. For example, the glass substrate 110 may be 100-150 μm (microns) thick or even more while the polymer layers 140, 130, 120 combined—where the passive elements are embedded—may only be about 50 μm thick. In other words, the glass substrate 110 dominates the thickness of the conventional POG device as a whole.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

An exemplary device is disclosed. The device may comprise a substrate, a passive component embedded in the substrate, and a support structure. The substrate may comprise a first layer with a first surface and a second layer with a second surface. The first and second surfaces may be opposite and exposed surfaces of the substrate. A first connect may be located in the first layer and a second connect may be located in the second layer. The first connect may be configured to electrically couple to the second connect. The support structure may be formed on and/or in the substrate. The support structure may also be configured to define an interior region. The first and second connects may be within the interior region. The first and second connects may also be respectively exposed at the first and second surfaces of the substrate.

An exemplary package is disclosed. The package may comprise a package substrate, a first redistribution layer on a first package surface of the package substrate, and a second redistribution layer on a second package surface of the package substrate. The passive-on-membrane package may also comprise one or more conductive vias within the package substrate. Each conductive via may be electrically coupled with the first redistribution layer and/or with the second redistribution layer. The package may further comprise a device configured to electrically couple with the first redistribution layer and/or with the second redistribution layer. The device may comprise a substrate, a passive component embedded in the substrate, and a support structure. The substrate may comprise a first layer with a first surface and a second layer with a second surface. The first and second surfaces may be opposite and exposed surfaces of the substrate. A first connect may be located in the first layer and a second connect may be located in the second layer. The first connect may be configured to electrically couple to the second connect. The support structure may be formed on and/or in the substrate. The support structure may also be configured to define an interior region. The first and second connects may be within the interior region. The first and second connects may also be respectively exposed at the first and second surfaces of the substrate.

An exemplary method of fabricating a device is disclosed. The method may comprise forming a plurality of devices, providing the plurality of devices on a first side and/or on a second side of a sacrificial carrier such that each adjacent pair of the devices on the first side and/or the second side are separated by a separation space, and removing the sacrificial carrier such that free standing plurality of devices remain. The process of forming the plurality of devices may comprise performing, for each device, providing a substrate which may include providing a first layer with a first surface and a second layer with a second surface of the substrate such that the first and second surfaces are opposite surfaces of the substrate, embedding a passive component in the substrate, and providing a first connect located in the first layer and a second connect located in the second layer such that the first connect is electrically coupled to the second connect. The process of removing the sacrificial carrier may comprise removing the sacrificial carrier to expose the first and second surfaces of the substrate such that the first and second connects are respectively exposed at the first and second surfaces of the substrate.

An exemplary device is disclosed. The device may comprise a substrate, a passive component embedded in the substrate, and means for providing support. The substrate may comprise a first layer with a first surface and a second layer with a second surface. The first and second surfaces may be opposite and exposed surfaces of the substrate. First means for routing signals may be located in the first layer and second means for routing signals may be located in the second layer. The first means for routing signals may electrically couple with the second means for routing signals. The means for providing support may be on and/or in the substrate. The means for providing support may define an interior region. The first and second means for routing signals may be within the interior region. The first and second means for routing signals may also be respectively exposed at the first and second surfaces of the substrate.

### BRIEF DESCRIPTION OF THE DRAWINGS

The accompanying drawings are presented to aid in the description of examples of one or more aspects of the disclosed subject matter and are provided solely for illustration of the examples and not limitation thereof.

FIGS. 1A and 1B illustrate examples of a conventional passive-on-glass device;

FIGS. 2A-2E illustrate examples of passive-on-membrane devices;

FIGS. 3A-3D illustrate examples of passive-on-membrane packages;

FIGS. 4A-4B, 5A-5B and 6-9 illustrate examples of different stages of fabricating a passive-on-membrane device;

FIG. 10 illustrates a flow chart of an example method of fabricating a passive-on-membrane device; and

FIG. 11 illustrates examples of devices with a passive-on-membrane device or package integrated therein.

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

As indicated above, conventional passives-on-glass (POG) has undesirable characteristics such as excessive thickness. Also, in conventional POG manufacturing, glass dicing has been a throughput bottleneck. This also increases costs. However, in a non-limiting aspect, it is proposed to provide passives-on-membrane (POM) devices, which are examples of passives in thin films, that is significantly thinner and provides similar or better performance than the conventional POG devices. The proposed POM devices may also be less expensive to fabricate than the conventional POG devices.

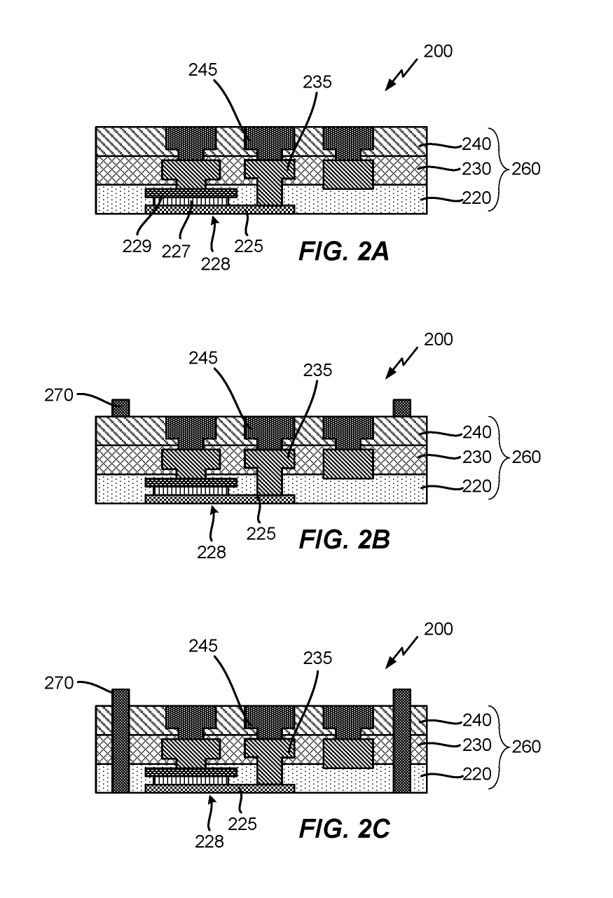

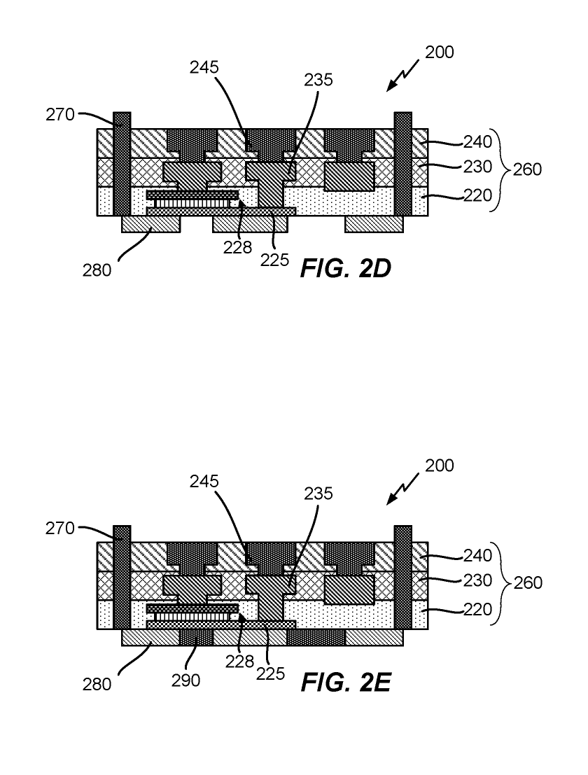

FIGS. 2A-2E illustrate non-limiting examples of devices such as passive-on-membrane (POM) devices. A POM device may include a plurality of substrate layers. In FIG. 2A, the example device 200 is illustrated as including first and second layers 240, 220. For ease of reference, the plurality of substrate layers 240, 230, 220 may be collectively referred to as the POM substrate 260 or simply as the substrate 260. It should be noted the substrate 260 can include any number of layers. For example, FIG. 2A illustrates that the substrate 260 may also include a third layer 230 in between the first and second layers 240, 220. Each layer 240, 230, 220 may be a polymer layer.

A top surface of the substrate 260 may be referred to as the front surface. Similarly, a bottom surface of the substrate 260 may be referred to as the back surface. Note that terms such as “front”, “back”, “top”, “bottom” and so on are used merely as terms of convenience, and should not be taken to be limiting. With the front and back surfaces of the substrate 260 so defined, then the first and second layers 240, 220 may also be respectively referred to as the front and back layers. Conversely, the front and back surfaces may be referred to as the first and second surfaces, which may be opposite and exposed surfaces of the substrate 260. Substrate layers such as the third layer 230 in between the front and back layers may be referred to as intermediate layers.

Within each layer of the substrate 260, there can be any number of connects. For example, the front (first) layer 240 may include one or more front (first) connects 245, the intermediate (third) layer 230 may include one or more intermediate (third) connects 235 and the back (second) layer 220 may include one or more back (second) connects 225. The connects 245, 235, 225 may be formed from electrically conductive materials such as copper.

The connects of adjacent layers may be electrically coupled with each other. For example, as seen in FIG. 2A, the first connect 245 may be in direct contact with the third connect 235. Also as seen, the third connect 235 may be electrically coupled with the second connect 225. In general, at least one connect of each layer may electrically couple with at least one connect of an adjacent layer. Further, at least one first connect 245 may be electrically coupled to at least one second connect 225 either directly (e.g., when there are no third layers 230) or through one or more third connects 235 (e.g., when there are one or more third layers 230).

While not shown in FIG. 2A, the connects 245, 235, 225 may also route electrical signals within the corresponding layer 240, 230, 220. This allows the signals to be routed laterally as well as vertically. In an aspect, the connects 245, 235, 225 may be viewed as means for routing signals within the layers 240, 230, 220, respectively.

Note that any number of passive components—e.g., capacitors, resistors, inductors—may be embedded or otherwise incorporated within the substrate 260. For example, a capacitor 228 may be embedded within the second layer 220. The capacitor 228 may include a dielectric 227 in between first and second electrodes 225, 229. In this particular instance, the second connect 225 may also serve as one of the electrodes of the capacitor 228. Note that the second electrode 229 may also be considered as a second connect. Of course, the passive elements 228 may be incorporated within any of the layers 240, 230, 220. It is also possible that the passive elements 228 may be incorporated to span multiple layers 240, 230, 220.

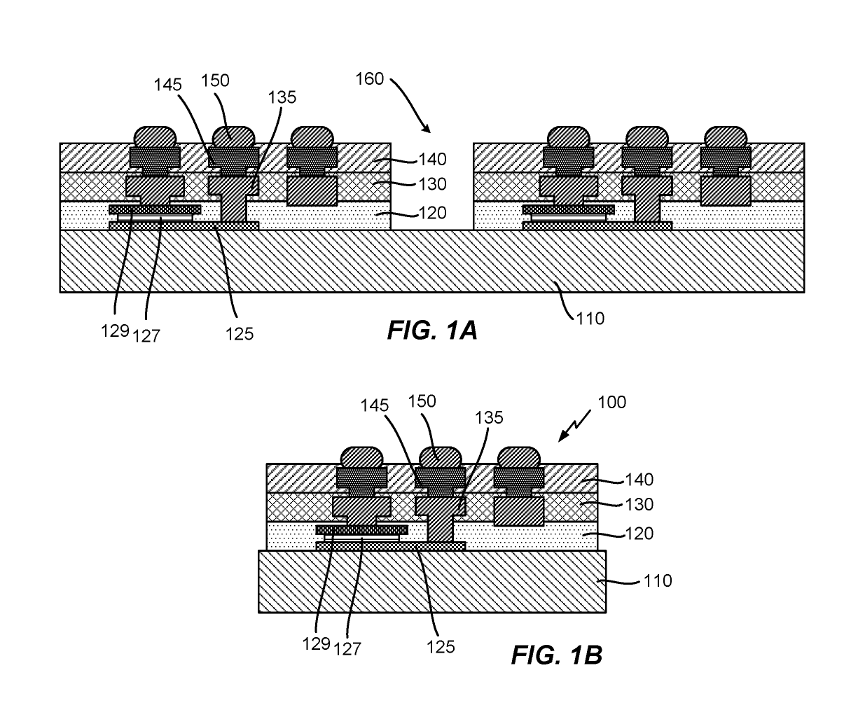

The device 200 in FIG. 2A differs from the conventional POG device 100 illustrated in FIGS. 1A and 1B in that the device 200 has no glass substrate. This can be very advantageous. First, the device 200 can be significantly thinner than the conventional POG device 100 (e.g., ˜50 μm vs. ˜150-200 μm). This means that the device 200 may be incorporated in device packages (explained further below) without substantially contributing to the total height of the package.

Second, both the first surface and the second surface of the substrate 260 may be exposed. In particular, the first connects 245 may be exposed at the first surface, and the second connects 225 may be exposed at the back surface. This means that the passive components 228 may be electrically accessed from both surfaces of the device 200. With the conventional POG device 100, access can be provided only from one surface due to the glass substrate 110.

For some applications, the device 200 illustrated in FIG. 2A may be too flexible, i.e., is not rigid enough. The device 200 of FIG. 2B may address the rigidity requirements as they arise. All components illustrated in FIG. 2A may also be included in FIG. 2B. But the device 200 of FIG. 2B may additionally include a support structure 270 to provide mechanical support to the substrate 260. That is, the support structure 270 may be more rigid than the substrate 260, i.e., more rigid than the plurality of layers 240, 230, 220. In this figure, two pillar-like structures on the left and right may be collectively referred to as the support structure 270.

Note that the support structure 270 would not be included in the conventional POG device 100. This is because the glass substrate 110 provides support. But as described, the glass substrate 110 comes with disadvantages. However, support structure 270 of the device 200 can provide the necessary mechanical support while incurring little to no penalties associated with the glass substrate 110 of the conventional POG device 100.

In an aspect, the support structure 270 may define an interior region such that the connects 245, 235, 225 are within the interior region. For example, as seen in FIG. 2B, the connects 245, 235, 225 may be inside the region defined by the two pillar-like structures. In an aspect, the support structure 270 may be an enclosure such as an annular ring. In another aspect, the support structure 270 may include multiple pillars.

The support structure 270 may be electrically isolated from the connects 245, 235, 225. In this way, the support structure 270 may provide the desired mechanical support without significantly affecting the electrical behavior of the passive components 228. In one implementation, the support structure 270 may be provided such that no physical contact occurs with the connects 245, 235, 225. Alternatively or in addition thereto, the support structure 270 may be formed from non-conductive materials.

FIG. 2B illustrates the support structure 270 formed on the first surface of the substrate 260. This is merely an example and should not be viewed in a limiting sense. Alternatively or in addition thereto, the support structure 270 may be formed on the second surface of the substrate 260 (not illustrated).

As illustrated in FIG. 2C, the support structure 270 may also be formed in the substrate 260. In this particular instance, the support structure 270 is illustrated as being embedded in the entire thickness of the substrate 260. This again is merely an example. While not illustrated, the support structure 270 may be partially embedded in the substrate 260. That is, the support structure 270 may be at least partially embedded in at least one layer 240, 230, 220. Also, while not shown, the support structure 270 need not protrude out of the substrate 270, i.e., the entirety of the support structure 270 may be within the substrate 260.

FIG. 2D illustrates another example of the device 200. The device in this figure may include all components of the device of FIG. 2A. But in addition, the device 200 of FIG. 2D may also include a passivation layer 280 on the first and/or the second surface of the substrate 260. The passivation layer 280 may have holes that expose portions of the first and/or the second surface. The holes may be provided such that one or more of the first connects 245 are exposed (when the passivation layer 280 is on the first surface) and/or such that one or more of the second connects 225 are exposed (when the passivation layer 280 is on the second surface). In this figure, the passivation layer 280 is illustrated as being formed on the second surface, and one of the holes exposes the second connect 225.

FIG. 2E illustrates yet another example of the device 200. The device in this figure may include all components of the device of FIG. 2D. But in addition, the device 200 of FIG. 2E may also include surface interconnects 290 that fill the holes of the passivation layer 280. When the passivation layer 280 is formed on the first surface (not shown), the surface interconnect 290 may be referred to as the front or the first surface interconnect 290 and may be electrically coupled with the exposed first connect 245. When the passivation layer 280 is formed on the second surface (shown in FIG. 2E), the surface interconnect 290 may be referred to as the back or the second surface interconnect 290 and may be electrically coupled with the exposed second connect 225.

It is emphasized that FIGS. 2A-2E illustrate examples of the devices 200. Other unillustrated combinations are contemplated. For example, as alternatives to the devices 200 of FIGS. 2D and 2E, some devices may include the passivation layer 280 but not include the support structure 270. Also while not shown, interconnects such as solder joints may be formed on the first connects 245.

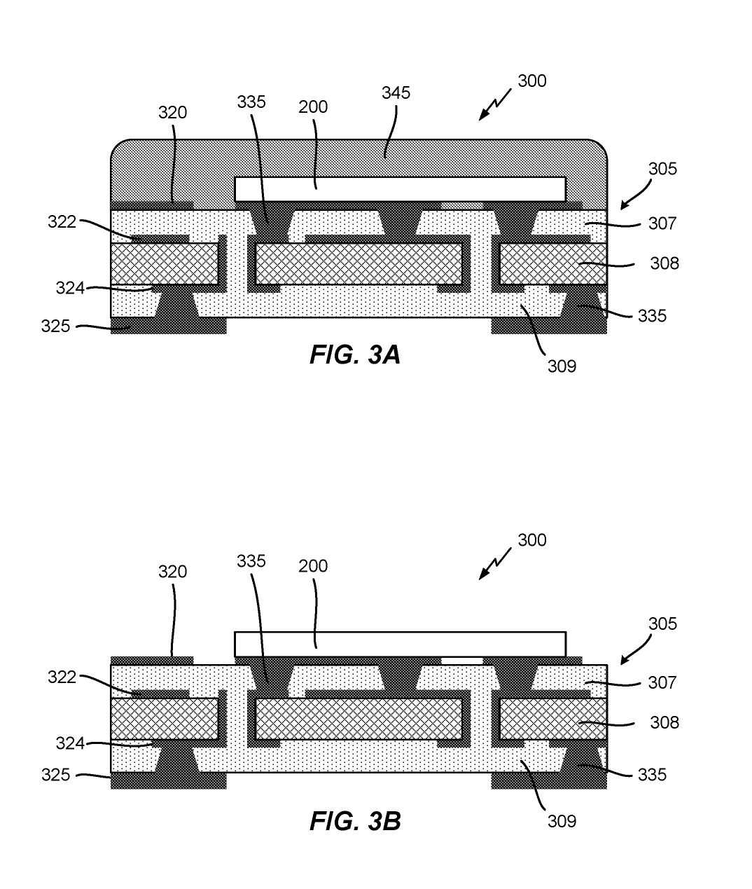

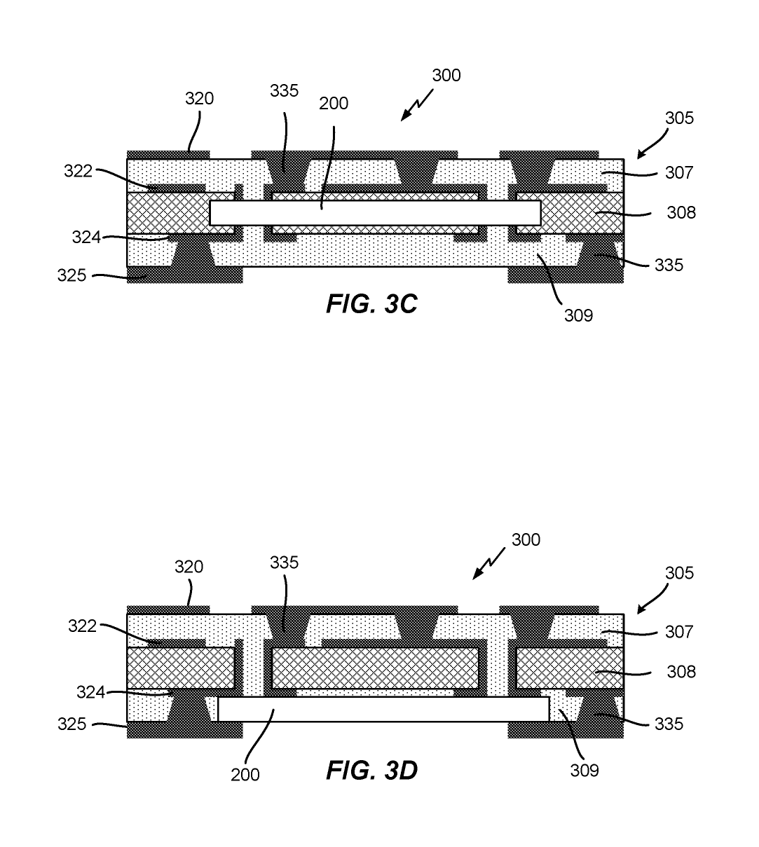

The devices 200 may be incorporated into packages. FIGS. 3A-3D illustrate examples of packages such as POM packages. As seen in FIG. 3A, the package 300 may include a package substrate 305, a first redistribution layer (RDL) 320 on a first package surface of the package substrate 305 and a second RDL 325 on a second package surface of the package substrate 305. The first and second RDLs 320, 325 may be formed from conductive materials such as copper.

The package substrate 305, e.g., a printed circuit board (PCB), may include any number of package layers such as package layers 307, 308 and 309. Any or all of the package layers 307, 308, 309 may be laminate layers. The package substrate 305 be coreless (not shown) or include a core. For example, the package layer 308 may be a core layer. When there are multiple package layers 307, 308, 309, there may be intermediate RDLs such as RDLs 322 and 324, which may be formed from copper. Electrical couplings between the package layers 307, 308, 309 may be provided through conductive vias 335. As seen, the conductive vias 335 in the package layer 307 may electrically couple with the first RDLs 320 with the intermediate RDLs 322. Also, the conductive vias 335 in the package layer 309 may electrically couple with the second RDLs 325 with the intermediate RDLs 324. The conductive vias 335 may be formed from conductive materials such as copper.

The package 300 may include a device 200 electrically coupled with the first RDL 320 and/or the second RDL 324. The device 200 may be any of the devices illustrated in FIGS. 2A-2E and unillustrated alternatives mentioned above. The device 200 may be provided on the first or the second package surface of the package substrate 305. When provided on the first package surface as seen in FIG. 3A, the device 200 may be electrically coupled with the first RDLs 320. For example, the second connects 225 (see FIGS. 2A, 2B, 2C) or the second surface interconnects 290 (see FIG. 2E) of the device 200 may be in direct contact with first RDLs 320. When the connects 245 and/or 225, the surface interconnects 290 and the RDLs 320 and/or 325 are formed from same conductive materials such as copper, then an advantageous copper-to-copper (Cu—Cu) bonding may be provided.

A molding 345, which encapsulates the device 200, may be formed on the first RDL 320 and on the first package surface of the package substrate 305. The molding 345 may provide protection and also provide reliability when interconnects, such as solder joints, are formed on the first connects 245 (not shown). But as seen in FIG. 3B, the molding 345 is not a strict requirement.

Due to its thinness, the device 200 may be encased, partially or entirely, within the package substrate 305. In FIG. 3C, the device 200 is illustrated as being encased within the core layer 308. For example, a cavity may be formed and the device 200 may be inserted within the cavity. FIG. 3C is but one of several possibilities. The device 200 can be embedded within any package layer, regardless of whether the package substrate 305 coreless or includes a core.

Indeed, the device 200 may also serve as one of the package layers. As seen in FIG. 3D, the device 200 may be made a part of the package layer 309. Again, the encasement may be partial or in the whole. In an aspect, the device 200 may be attached to the package substrate 305 on the second surface of the device 200, and the first surface may be exposed. The second interconnects 225 or the second surface interconnects 290 may electrically couple with the intermediate RDLs 324 (e.g., through direct contact).

When the device 200 is encased (in part or in entirety) within the package substrate 305, a functional IPD (integrated passive device) can be incorporated into the package substrate 305.

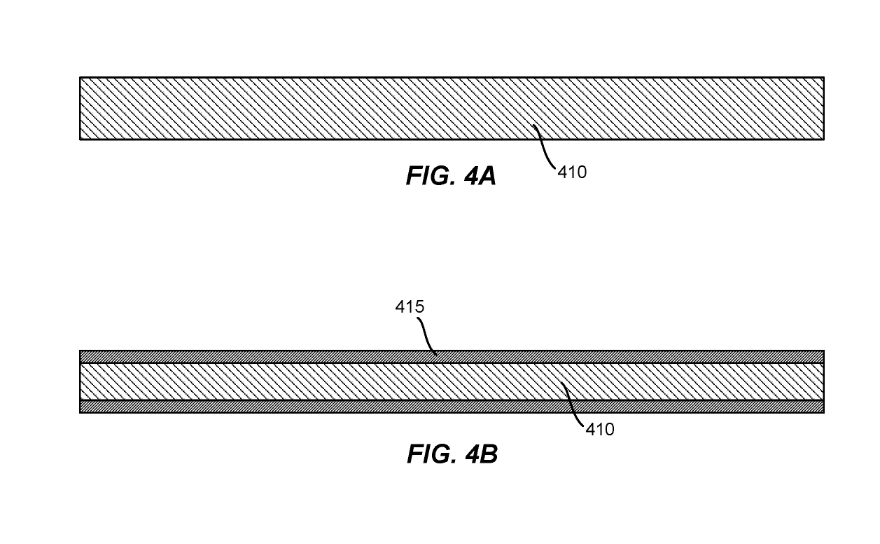

FIGS. 4A-4B, 5A-5B and 6-9 illustrate examples of different stages of fabricating devices such as those illustrated in FIGS. 2A-2E. However, the illustrated stages are also applicable to the unillustrated alternative devices. Both FIGS. 4A and 4B illustrate stages in which a sacrificial carrier 410, 415 may be provided. The sacrificial carrier 410, 415 can be a single material or a combination of materials. For example, in FIG. 4A, the sacrificial carrier 410 can be a glass or silicon, and in FIG. 4B, the sacrificial carrier 410, 415 can be a combination of amorphous silicon (a-Si) on one or both sides of the glass.

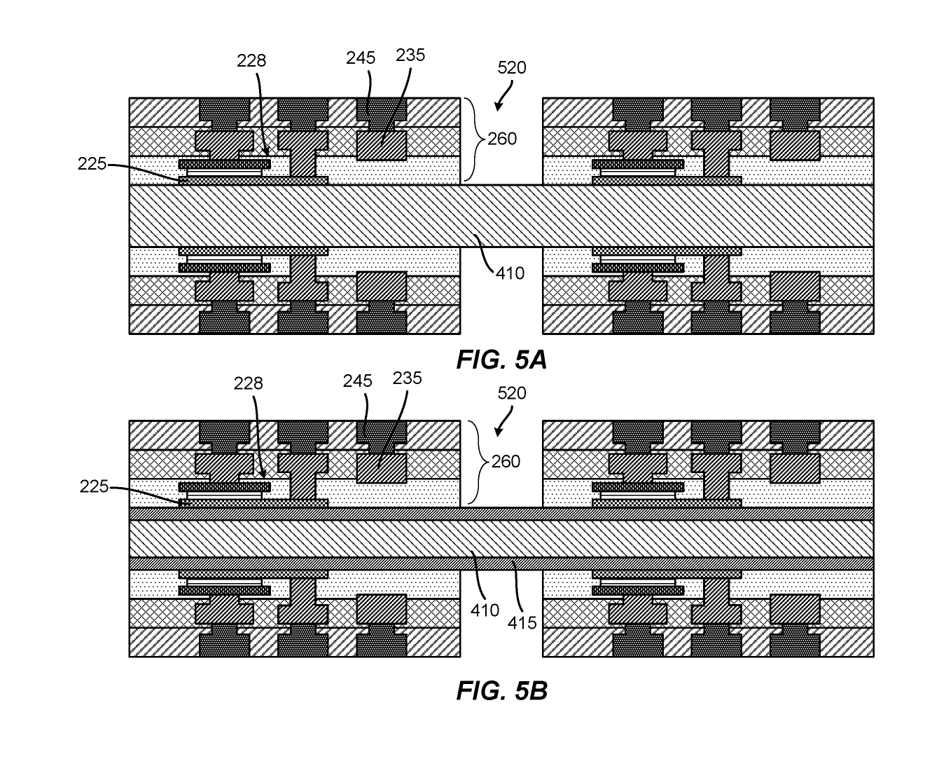

FIG. 5A illustrates a stage in which a plurality of devices 200 may be provided on both sides of the single material sacrificial carrier 410, and FIG. 5B illustrates a stage in which the plurality of devices 200 may be provided on both sides of the combination of materials sacrificial carrier 410, 415. While not shown, it is also possible to provide the plurality of devices 200 on only one side of the sacrificial carrier 410, 415. However, providing the devices 200 on both sides may be preferred for reasons such as costs.

Note that separation spaces 520 may separate adjacent pair of devices 200 and also expose the sacrificial carrier 410, 415. While not shown, the separation spaces 520 may be provided lithographically. For example, the plurality of devices 200 may initially be provided on the sacrificial carrier 410, 415 as a continuous strip. Then a photomask may be applied to expose the portions of the strip corresponding to the separation space 520, and then the exposed portions may be etched.

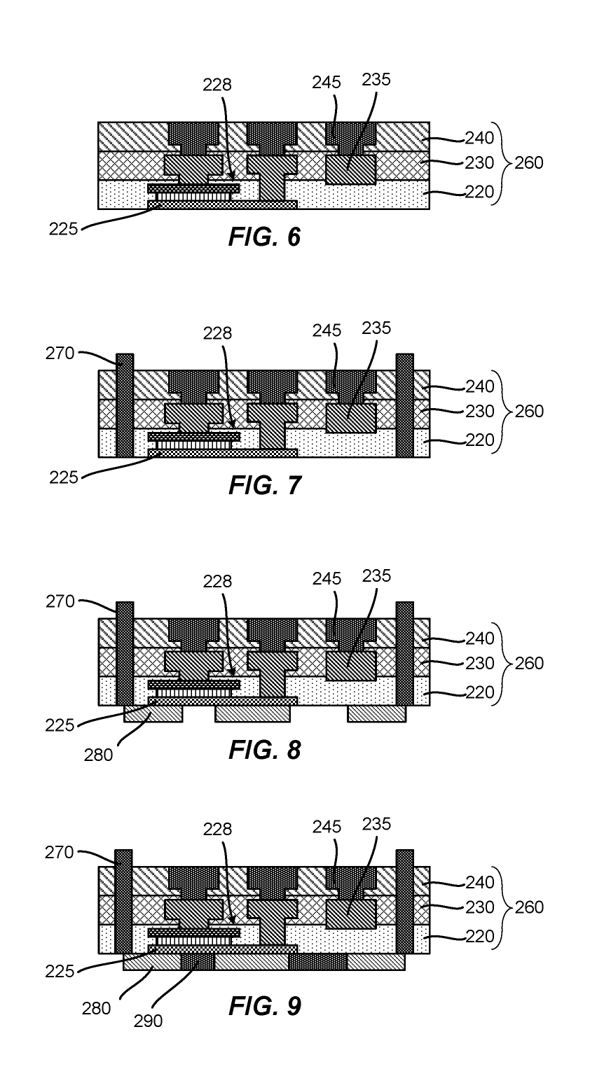

FIG. 6 illustrates a stage in which the sacrificial carrier 410, 415 is removed. When the sacrificial carrier 410, 415 is removed, what remains is a plurality of freestanding devices 200, one of which is shown in FIG. 6. In an aspect, the sacrificial carrier 410, 415 may be chemically etched through the separation space 520. For example, when the sacrificial carrier 410 is glass, vapor HF may be used as an etchant. When the sacrificial carrier 410 is silicon, XeF2 may be used. When the sacrificial carrier 410, 415 is a combination of glass and a-Si, XeF2 may be used to etch the a-Si and HF may be used to etch the glass thereafter.

FIG. 7 illustrates a stage in which the support structure 270 is formed. This stage, which is optional, may follow the stage illustrated in FIG. 6. The support structure 270 may be formed on the first surface and/or the second surface of the substrate 260. Alternatively or in addition thereto, the support structure 270 may be formed in the substrate 260.

FIG. 8 illustrates a stage in which the passivation layer 280 is formed. This stage, which is optional, is illustrated as following the stage of FIG. 7. However, the passivation layer 280 may also be formed following the stage of FIG. 6. The passivation layer 280 may be formed on the first surface and/or on the second surface of the substrate 260. When desired, the passivation layer 280 may be provided with holes, e.g., through lithography and etching processes.

FIG. 9 illustrates a stage in which the surface interconnects 290 are formed in the holes of the passivation layer 280. This stage, which is optional, may follow the stage of FIG. 8. For example, a conductive material such as copper may be deposited on the passivation layer 280 and in the holes. Thereafter, the deposited materials may be polished (e.g., CMP). FIG. 9 shows the passivation layer 280 and the surface interconnects 290 formed on the second surface of the substrate 260. Alternatively or in addition thereto, the passivation layer 280 and the surface interconnects 290 may also be formed on the first surface of the substrate 260.

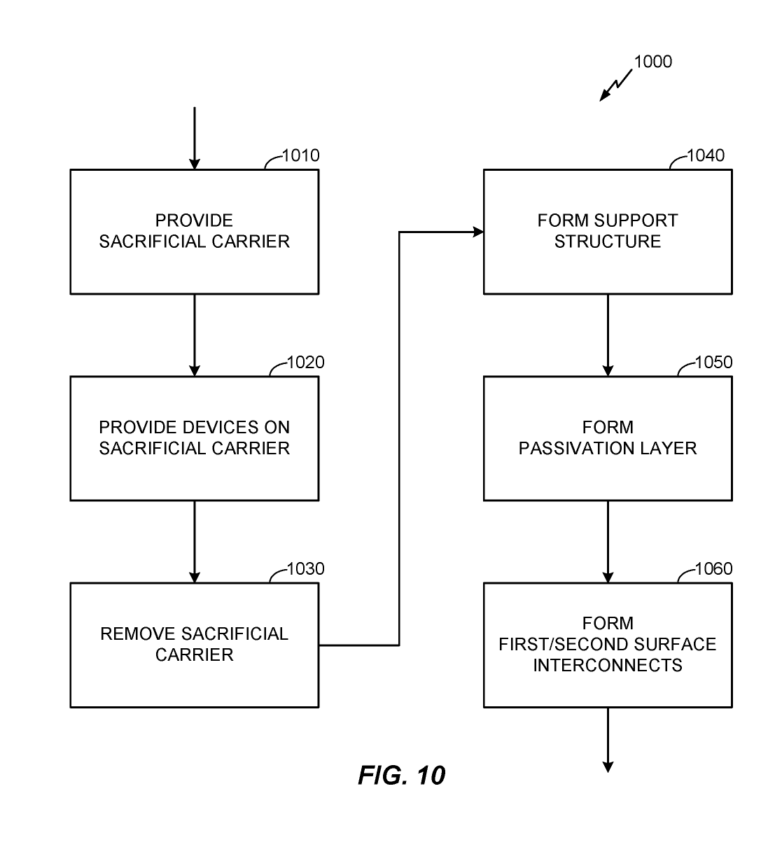

FIG. 10 illustrates a flow chart of an example method 1000 of fabricating a device such as the devices illustrated in FIGS. 2A-2E. It should be noted that not all illustrated blocks of FIG. 10 need to be performed, i.e., some blocks may be optional. Also, the numerical references to the blocks of FIG. 10 should not be taken as requiring that the blocks should be performed in a certain order.

In block 1010, the sacrificial carrier 410, 415 may be provided. A single material such as glass or silicon may be prepared as the sacrificial carrier 410. Alternatively, a combination of materials such as glass and amorphous silicon may be prepared as the sacrificial carrier 410, 415. Block 1010 may correspond to the stages illustrated in FIGS. 4A and 4B.

In block 1020, a plurality of devices 200 may be provided on the sacrificial carrier 410, 415. The devices 200 may be provided on the first side and/or the second side of the sacrificial carrier 410, 415. The devices 200 may be provided such that adjacent pair of devices 200 are separated by separation spaces 520. The separation spaces 520 may also expose portions of the sacrificial carrier 410, 415. Block 1020 may correspond to the stages illustrated in FIGS. 5A and 5B.

In block 1030, the sacrificial carrier 410, 415 may be removed such that free standing devices 200 remain Removing the sacrificial carrier 410, 415 may be accomplished by chemically etching the sacrificial carrier 410, 415 through the separation space 520. For glass, vapor HF may be used. For Si or a-Si, XeF2 may be used. Block 1030 may correspond to the stage illustrated in FIG. 6.

If desired, the support structure 270 may be formed in block 1040. The support structure 270 may define an interior region such that the connects 245, 235, 225 are within the interior region. The support structure 270 may be formed on the first and/or the second surface of the substrate 260. Alternatively or in addition thereto, the support structure 270 may be formed in the substrate 260. For example, support structure 270 may be at least partially embedded in at least one substrate layer 240, 230, 220. Block 1040 may correspond to the stage illustrated in FIG. 7.

If desired, the passivation layer 280 may be formed in block 1050. The passivation layer 280 may be formed on the first and/or the second surface of the substrate 260. Holes may be provided in the passivation layer 280 to expose portions of the first and/or the second surface of the substrate 260. Block 1050 may correspond to the stage illustrated in FIG. 8.

If desired, the holes in the passivation layer 280 may be filled with surface interconnects 290 in block 1060. When the passivation layer 280 is formed on the first surface of the substrate 260, the surface interconnects 290, also referred to as the first surface interconnects 290, may electrically couple with the first connects 245. When the passivation layer 280 is formed on the second surface of the substrate 260, the surface interconnects 290, also referred to as the second surface interconnects 290, may electrically couple with the second connects 225. Block 1060 may correspond to the stage illustrated in FIG. 9.

The devices described above provide numerous advantages over the conventional POG devices. The devices enable significant height reduction by removing the glass substrate. For the described devices, air may serve as the dielectric. So there is little to no transient loss. The devices may also improve solder joint reliability, e.g., when solder joints are formed as interconnects on the first connects 245. When conventional POG devices 100 are attached to a PCB substrate, there can be a significant CTE (coefficient of thermal expansion) mismatch between the Si or glass substrate and the PCB substrate. But with the described devices, substantially better CTE match may be provided. In some instances, the solder joints may not even be necessary such as when Cu—Cu bondings are provided. In addition, the double sided process may provide a better cost structure relative to fabricating conventional POG devices. Yet further, no dicing—laser or saw—is required. The removal of the sacrificial layer 410, 415 may serve as the equivalent dicing function.

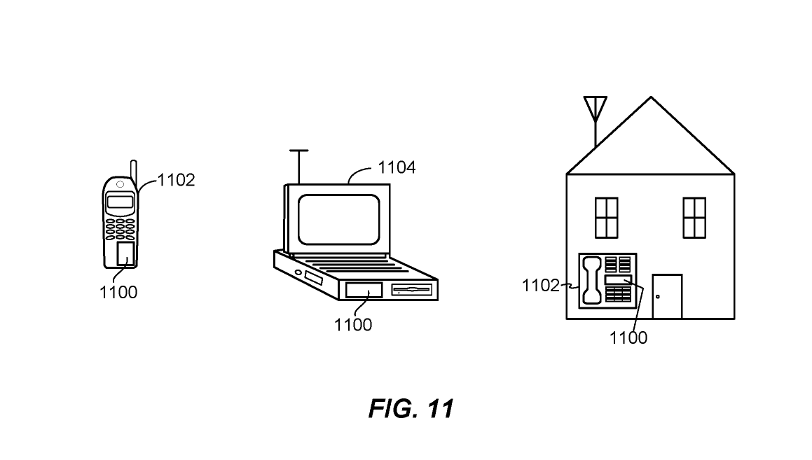

FIG. 11 illustrates various electronic devices that may be integrated with any of the aforementioned devices 200 or the package 300. For example, a mobile phone device 1102, a laptop computer device 1104, and a fixed location terminal device 1106 may include a device/package 1100 as described herein. The device/package 1100 may be, for example, any of the integrated circuits, dies, integrated devices, integrated device packages, integrated circuit devices, device packages, integrated circuit (IC) packages, package-on-package devices described herein. The devices 1102, 1104, 1106 illustrated in FIG. 11 are merely exemplary. Other electronic devices may also feature the semiconductor device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the examples disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled with the processor such that the processor can read information from, and write information to, the storage medium. In the alternative, the storage medium may be integral to the processor.

Accordingly, an aspect can include a computer readable media embodying a method of forming a semiconductor device. Accordingly, the scope of the disclosed subject matter is not limited to illustrated examples and any means for performing the functionality described herein are included.

While the foregoing disclosure shows illustrative examples, it should be noted that various changes and modifications could be made herein without departing from the scope of the disclosed subject matter as defined by the appended claims. The functions, processes and/or actions of the method claims in accordance with the examples described herein need not be performed in any particular order. Furthermore, although elements of the disclosed subject matter may be described or claimed in the singular, the plural is contemplated unless limitation to the singular is explicitly stated.

1. A device, comprising:
a substrate comprising a first layer with a first surface and a second layer with a second surface, wherein the first and second surfaces are opposite and exposed surfaces of the substrate;
a passive component embedded in the substrate;
a first connect located in the first layer and a second connect located in the second layer, wherein the first connect is configured to electrically couple to the second connect; and
a support structure formed on and/or in the substrate and configured to define an interior region,
wherein the first and second connects are within the interior region, and are respectively exposed at the first and second surfaces of the substrate.

2. The device of claim 1, wherein the support structure is configured to be electrically isolated from the first and second connects.

3. The device of claim 1, wherein the support structure is configured to surround the first and second connects.

4. The device of claim 1, wherein the support structure is formed on the first surface and/or on the second surface of the substrate.

5. The device of claim 1, wherein the support structure is embedded at least partially in the substrate.

6. The device of claim 5, wherein the support structure is embedded in an entire thickness of the substrate.

7. The device of claim 1, further comprising a passivation layer on the second surface of the substrate.

8. The device of claim 7, wherein the passivation layer has a hole configured to expose a portion of the second surface of the substrate.

9. The device of claim 8, further comprising a surface interconnect configured to fill the hole of the passivation layer and to electrically couple with the second connect.

10. The device of claim 1, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

11. A package comprising:
a package substrate;
a first redistribution layer (RDL) on a first package surface of the package substrate;
a second RDL on a second package surface of the package substrate;
one or more conductive vias within the package substrate, each conductive via configured to electrically couple with the first RDL and/or with the second RDL; and
a device configured to electrically couple with the first RDL and/or with the second RDL, the device comprising:
a substrate comprising a first layer with a first surface and a second layer with a second surface, wherein the first and second surfaces are opposite and exposed surfaces of the substrate;
a passive component embedded in the substrate;
a first connect located in the first layer and a second connect located in the second layer, wherein the first connect is configured to electrically couple to the second connect; and
a support structure formed on and/or in the substrate and configured to define an interior region,
wherein the first and second connects are within the interior region, and are respectively exposed at the first and second surfaces of the substrate.

12. The package of claim 11, wherein the support structure is embedded at least partially in the substrate.

13. The package of claim 11, wherein the device is on and configured to electrically couple with the first RDL.

14. The package of claim 13, further comprising a molding on the first RDL and on the first package surface of the package substrate, the molding encapsulating the device.

15. The package of claim 13, wherein the first RDL is configured to electrically couple with the first connect or with the second connect.

16. The package of claim 15, wherein the first RDL is in direct contact with one of the first connect and the second connect.

17. The package of claim 16, wherein the first RDL is formed from a same material as the first connect and/or the second connect.

18. The package of claim 15,
wherein the device further comprises:
a passivation layer on the second surface of the substrate, the passivation layer having a hole configured to expose a portion of the second surface of the substrate; and
a surface interconnect configured to fill the hole of the passivation layer and electrically couple with the second connect, and
wherein the first RDL is in direct contact with the surface interconnect.

19. The package of claim 15, wherein the first RDL is formed from a same material as the surface interconnect.

20. The package of claim 11, wherein the device is entirely encased within the package substrate.

21. The package of claim 11,
wherein the package substrate comprises a plurality of laminate layers, and
wherein the device is at least partially encased within one of the plurality of laminate layers.

22. A method comprising:
forming a plurality of devices;
providing the plurality of devices on a first side and/or on a second side of a sacrificial carrier such that each adjacent pair of the devices on the first side and/or the second side are separated by a separation space; and
removing the sacrificial carrier such that free standing plurality of devices remain,
wherein forming the plurality of devices comprises performing for each device:
providing a substrate, wherein providing the substrate includes providing a first layer with a first surface and a second layer with a second surface of the substrate such that the first and second surfaces are opposite surfaces of the substrate;
embedding a passive component in the substrate; and
providing a first connect located in the first layer and a second connect located in the second layer such that the first connect is electrically coupled to the second connect,
wherein removing the sacrificial carrier comprises removing the sacrificial carrier to expose the first and second surfaces of the substrate such that the first and second connects are respectively exposed at the first and second surfaces of the substrate.

23. The method of claim 22, wherein removing the sacrificial carrier comprises etching the sacrificial carrier chemically through the separation space.

24. The method of claim 23, wherein removing the sacrificial carrier comprises:
etching the sacrificial carrier using HF when the sacrificial carrier comprises glass; and
etching the sacrificial carrier using XeF2 when the sacrificial carrier comprises silicon (Si).

25. The method of claim 23, wherein removing the sacrificial carrier comprises:
etching the sacrificial carrier using XeF2 to remove an amorphous silicon (a-Si) part of the sacrificial carrier; and
etching the sacrificial carrier using HF to remove a glass part of the sacrificial carrier.

26. The method of claim 22, further comprising forming a support structure on and/or in the substrate such that the first and second connects are within an interior region defined by the support structure, and the support structure is electrically isolated from the first and second connects.

27. The method of claim 26, wherein forming the support structure comprises embedding the support structure at least partially in the substrate.

28. The method of claim 22, further comprising forming a passivation layer on the second surface of the substrate such that the passivation layer has a hole exposing a portion of the second surface.

29. The method of claim 28, further comprising forming a surface interconnect such that the surface interconnect fills the hole of the passivation layer and electrically couples with the second connect.

30. A device, comprising:
a substrate comprising a first layer with a first surface and a second layer with a second surface, wherein the first and second surfaces are opposite and exposed surfaces of the substrate;
a passive component embedded in the substrate;
first means for routing signals located in the first layer and second means for routing signals located in the second layer, wherein the first means for routing signals electrically couples with the second means for routing signals; and
means for providing support on and/or in the substrate, wherein the means for providing support defines an interior region,
wherein the first and second means for routing signals are within the interior region, and are respectively exposed at the first and second surfaces of the substrate.
